(19) United States
(12) Patent Application Publication
(10) Pub. No.: US 2024/0258211 A1
(43) Pub. Date: Aug. 1, 2024

(54) SEMICONDUCTOR DEVICE PACKAGE WITH ISOLATION

(71) Applicant: Texas Instruments Incorporated, Dallas, TX (US)

(72) Inventors: Sreenivasan K. Koduri, Dallas, TX (US); Ryan Thorpe, Allen, TX (US); Hank M. Sung, Allen, TX (US)

(21) Appl. No.: 18/160,226

(22) Filed: Jan. 26, 2023

(51) Int. Cl. H01L 23/495; H01L 21/48; H01L 23/00; H01L 23/31; H10N 59/00

(52) U.S. Cl. CPC H01L 23/49558; H01L 21/4839; H01L 23/3107; H01L 23/49513; H01L 23/49555; H01L 24/29; H01L 24/32; H01L 24/48; H01L 24/73; H01L 24/85; H10N 59/00; H01L 24/45; H01L 2224/2919; H01L 2224/32225; H01L 2224/45124; H01L 2224/45139; H01L 2224/45144; H01L 2224/45147; H01L 2224/45664; H01L 2224/48151; H01L 2224/48465; H01L 2224/73215; H01L 2224/85

(57) ABSTRACT

An example apparatus includes a metal leadframe that includes: first leads in a first portion; second leads in a second portion spaced from the first leads, the second leads isolated from the first leads; an isolation barrier mounted to a board side surface of the first portion of the metal leadframe; a semiconductor die mounted to the isolation barrier, the semiconductor die having a sensor on a device side surface facing the first portion of the leadframe, the semiconductor die cantilevered and having bond pads on the device side surface exposed in the opening in the metal leadframe; electrical connections coupling the bond pads and second leads in the second portion of the metal leadframe; and mold compound covering the semiconductor die, the electrical connections, the isolation barrier and portions of the first leads and the second leads, the mold compound forming a package body.

### TECHNICAL FIELD

This disclosure relates generally to semiconductor device packages, and more particularly to semiconductor device packages including a semiconductor die mounted to and isolated from a leadframe. In semiconductor device packages with sensors and isolation, a leadframe has a portion for carrying a signal that is electrically isolated from a semiconductor die with a sensor, and another portion of the leadframe can carry signals from the semiconductor die to external leads.

### BACKGROUND

Processes for producing semiconductor device packages with isolation include mounting a semiconductor die to an isolation barrier that is further mounted to a package substrate, making electrical connections from the semiconductor die to the package substrate, and covering the electronic devices with a protective dielectric material such as a mold compound to form semiconductor device packages. In some examples the package substrate can be a leadframe with isolated portions, some leads are coupled to the semiconductor die for external connections, and some leads are coupled to a voltage, current or surface for sensing.

In a particular type of sensor, a Hall-effect device is used to sense a magnetic field that occurs when a current is conducted through a conductor. By coupling the current through a leadframe portion that forms a conductor, and by placing a semiconductor die with the Hall-effect device formed on it in proximity to but electrically isolated from the current carrying conductor, a measurement of the current can be made by the Hall-effect device. The amount of signal gain that is obtained is inversely proportional to the distance from the conductor to the Hall-effect device, which can be fabricated on a device side surface of a semiconductor die.

The components in an isolated package with a sensor can include an isolation barrier, which is an insulating dielectric arranged to provide additional electrical isolation, a semiconductor die which was fabricated as part of a semiconductor wafer, and the other materials between the sensor on the semiconductor die and the leadframe, which can include die attach material and passivation layers such as polyimide. The thickness of these materials and the die mounting orientation are important factors in designing the semiconductor device packages with isolation.

When a wire bonded semiconductor die mount is used, the semiconductor die may be mounted facing away from the package substrate (for example, a leadframe) with bond wires coupling bond pads on the device side surface of the semiconductor die to conductive leads. In an isolation semiconductor device package a portion of the leadframe may be electrically isolated from the semiconductor die using an isolation barrier. A sensor formed on the semiconductor die is thus oriented facing away from the leadframe and is spaced from the leadframe by the thickness of the semiconductor die, which can be between 200 and 400 microns, for example, and also by the thickness of the isolation barrier. Because the gain of the sensor (a magnetic sensor such as a Hall-effect device, for example) is inversely proportional to the total distance from the sensor (on the device side surface of the semiconductor die) to the leadframe carrying the signal to be sensed, the sensor gain is reduced by the thickness of the semiconductor die itself when the semiconductor die is mounted in the face up orientation, that is facing away from the leadframe.

When a flip chip semiconductor die mounting is used, a semiconductor die has bond pads on the device side surface, and conductive post connects extend perpendicularly from the bond pads. The semiconductor die is mounted “flipped” or “face down” with the device side of the semiconductor die facing the package substrate (for example, a leadframe) and the isolation barrier. The thickness of the isolation barrier and the die attach materials substantially contribute to the distance between the sensor on the semiconductor die and the leadframe, however the semiconductor die thickness does not contribute to the distance, and therefore the flip chip orientation has relatively good sensor gain when compared to the wire bonded isolation package, because the total distance between the leadframe and the sensor is reduced. However, flip chip semiconductor device packages are costly compared to wire bonded packages, and low cost is increasingly important for sensor devices.

A semiconductor device package having a sensor on a semiconductor die that is isolated from a signal, current or voltage to be sensed that is carried by a leadframe, having low cost and relatively high signal gain to the sensor, is needed.

### SUMMARY

An example apparatus includes: a metal leadframe, including first leads in a first portion, and second leads in a second portion spaced from the first leads by an opening, the second leads isolated from the first leads. An isolation barrier is mounted to a board side surface of the first portion of the metal leadframe. A semiconductor die having a device side surface is mounted to the isolation barrier using die attach material, the semiconductor die having a sensor on the device side surface facing the first portion of the leadframe, the semiconductor die being cantilevered and having bond pads on the device side surface exposed in the opening in the leadframe. Electrical connections are formed coupling the bond pads and second leads formed in the second portion of the metal leadframe. Mold compound is formed covering the semiconductor die, the electrical connections, the isolation barrier and portions of the first leads and the second leads, the mold compound forming a package body.

An example method includes: mounting an isolation barrier to a first portion of a metal leadframe, the metal leadframe having first leads in the first portion, an opening in a central portion, and second leads in a second portion spaced from the first leads of the first portion by the opening; mounting a semiconductor die to the isolation barrier, the semiconductor die having a sensor on a device side surface that is mounted facing the first portion of the metal leadframe, the semiconductor die being cantilevered with bond pads on the device side surface positioned in the opening and facing the metal leadframe; making electrical connections from the bond pads to the second leads in the second portion of the metal leadframe; and covering the semiconductor die, the electrical connections, portions of the first leads of the metal leadframe and portions of the second leads of the metal leadframe with mold compound to form a semiconductor device package.

### BRIEF DESCRIPTION OF THE DRAWINGS

FIGS. 1A-1B illustrate, in a projection view and a close up projection view, respectively, semiconductor dies on a semiconductor wafer, and an individual semiconductor die from the semiconductor wafer for use with the arrangements.

FIG. 2 illustrates, in a top view, a semiconductor device package that is useful in an arrangement.

FIG. 3 illustrates, in a top view, an alternative semiconductor device package for use with a another arrangement.

FIGS. 4A-4H illustrate, in a series of views, selected steps for forming semiconductor device packages of the arrangements.

FIG. 5 illustrates, in a projection view, an alternative arrangement for a semiconductor device package.

FIGS. 6A-6C illustrate, in a top view and two cross sectional views, respectively, additional details of a semiconductor device package of an arrangement.

FIG. 7 illustrates, in a block diagram, a circuit that can be used with an example arrangement.

FIG. 8 illustrates, in a flow diagram, a method for forming a semiconductor device package of the arrangements.

### DETAILED DESCRIPTION

Corresponding numerals and symbols in the different figures generally refer to corresponding parts, unless otherwise indicated. The figures are not necessarily drawn to scale.

Elements are described herein as “coupled.” The term “coupled” includes elements that are directly connected and elements that are indirectly connected, and elements that are electrically connected even with intervening elements, conductors, or wires are coupled. In an example arrangement, a sensor receives a magnetic field from a conductor carrying current and is coupled to the conductor, even though the sensor is isolated from the conductor, and no current flows between the sensor and the conductor.

The term “semiconductor die” is used herein. The semiconductor die can include passive devices such as resistors, inductors, filters, sensors, or active devices such as transistors. The semiconductor die can be an integrated circuit with hundreds or thousands of transistors coupled to form a functional circuit, for example a microprocessor or memory device. In an example arrangement, the semiconductor die can include a Hall-effect sensor.

The term “semiconductor device package” is used herein. A semiconductor device package has at least one semiconductor die electrically coupled to terminals, and has a package body that protects and covers the semiconductor die. The semiconductor device package can include additional elements. Passive components such as sensors, antennas, capacitors, coils, inductors, and resistors can be included. In some arrangements, multiple semiconductor dies can be packaged together. For example, a sensor and associated amplifiers, signal filters, offset circuitry, compensation circuitry, and reference circuitry can be integrated on a semiconductor die that provides an output signal proportional to a sensed parameter. In a particular example a Hall-effect sensor is used. Position sensors, voltage sensors, current sensors, and magnetic field sensors can be used. Circuitry that combines functions such as a sensor and an amplifier semiconductor die and/or a logic semiconductor die (such as a controller die or digital filter) can be packaged together to from a single semiconductor device package. The semiconductor die is/are mounted to a package substrate that provides conductive leads. A portion of the conductive leads form external leads for the packaged device. In wire bonded semiconductor device packages used in the arrangements, bond wires or ribbon bonds couple conductive leads of a package substrate to bond pads on the semiconductor die. The semiconductor device package can have a package body formed by a thermoset epoxy resin in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation, these exposed lead portions provide the external leads for the semiconductor device package.

The terms “high voltage” and “low voltage” are used herein. A “high voltage” is a voltage greater than about twenty volts, and up to several hundred volts. High voltages are voltages that exceed the normal operating voltages for a silicon semiconductor device, and accordingly, the arrangements include isolation between a first portion of a package substrate that has leads configured for the high voltage, and a second portion of the package substrate that has leads configured for the low voltage and which are connected to the semiconductor die in the package. A “low voltage” is a voltage less than 20 volts, and can include voltages compatible with silicon semiconductor device supplies and operations, such as 6 volts, 5 volts, 3 volts, 2.8 volts or even less.

The term “package substrate” is used herein. A package substrate is a substrate arranged to receive a semiconductor die and to support the semiconductor die in a completed semiconductor device package. Package substrates can include conductive metal leadframes, which can be formed from copper, aluminum, stainless steel, steel and alloys such as Alloy 42 and copper alloys. In the arrangements, leadframes are arranged to have two portions spaced from one another so that certain leads can be electrically isolated from the remaining leads and from a semiconductor die coupled to the remaining leads. Conductive leads are configured for coupling to bond pads on the semiconductor die. In an example arrangement, the electrical connections from the bond pads to the leads are formed using wire bonds, ribbon bonds, or other conductors. The leadframes can be provided in strips, grids or arrays. The conductive leadframes can be provided as a panel or grid with strips or arrays of unit leadframe portions placed in rows and columns. Semiconductor dies can be placed on respective unit leadframe portions within the strips or arrays for processing.

In packaging semiconductor devices, mold compound may be used to partially cover a package substrate, to cover components, to cover a semiconductor die or multiple semiconductor dies, and to cover the electrical connections from the semiconductor die or dies to the package substrate. This molding process can be referred to as an “encapsulation” process, although some portions of the package substrates are not covered in the mold compound during encapsulation. For example, in the arrangements portions of the leads are left exposed from the mold compound and these exposed portions form terminals for making connections to a semiconductor device package. Encapsulation is often a compressive molding process, where thermoset mold compound such as resin epoxy can be used. Mold compound used in electronic packaging is sometimes referred to as “EMC” or “epoxy mold compound.” A room temperature solid or solid powder mold compound can be heated to a liquid state, and then transfer molding can be performed by pressing the liquid mold compound into a mold through runners or channels. Unit molds shaped to surround an individual device may be used, or block molding may be used. The molding process forms multiple packages simultaneously for several devices. The devices to be molded can be provided in an array or matrix of several, hundreds or even thousands of devices in rows and columns on a leadframe strip. The semiconductor devices are then molded at the same time to increase production throughput.

After molding, the individual packaged semiconductor devices are cut from one another in a sawing operation by cutting through the mold compound and package substrate in saw streets that are defined between the molded semiconductor devices. In some arrangements, leaded semiconductor device packages used, with a portion of the leads extending outside of the package body formed by the mold compound to form external terminals for solder mounting. The leads can be formed to have feet or bottom surfaces arranged for a solder surface mount operation, such as a solder reflow operation, to form physical connection and electrical coupling of the packaged device to a printed circuit board or module. In other alternative arrangements, no lead semiconductor device packages are used, with terminals formed within the boundaries of the semiconductor device package, reducing board area needed to mount the devices.

The term “scribe lane” is used herein. A scribe lane is a portion of semiconductor wafer between semiconductor dies. Sometimes the term “scribe street” is used. Once semiconductor processing is completed and the semiconductor devices are complete, the semiconductor devices are separated into individual semiconductor dies by severing the semiconductor wafer along the scribe lanes. The separated dies can then be removed and handled individually for further processing. This process of removing semiconductor dies from a wafer is referred to as “singulation” or sometimes referred to as “dicing.” Scribe lanes are arranged on four sides of semiconductor dies and when the dies are singulated from one another, rectangular semiconductor dies are formed.

The term “saw street” is used herein. A saw street is an area defined between molded electronic devices used to allow a saw, such as a mechanical blade, laser or other cutting tool to pass between the molded electronic devices to separate the devices from one another. This process is another form of singulation. When the molded electronic devices are provided in a strip with one device adjacent another device along the strip, the saw streets are parallel to one another and normal to the length of the strip. When the molded electronic devices are provided in an array of devices in rows and columns, the saw streets include two groups of parallel saw streets, the two groups are normal to each other and the saw will traverse the molded electronic devices in two different directions to cut apart the packaged electronic devices from one another in the array.

The terms “cantilever”, “cantilevered” and “being cantilevered” are used herein. An element that is a cantilever is supported at one end. In the arrangements, a semiconductor die is cantilever mounted, with one end mounted to an isolation barrier that is mounted to a portion of a leadframe, while the opposite end of the semiconductor die extends into an opening in the leadframe and is unsupported, bond pads on the semiconductor die are exposed in the opening for wire bond connections. The semiconductor die is described as cantilevered, or being cantilevered, or in a cantilever mount.

In an example arrangement, a hybrid semiconductor device package includes a leadframe portion configured to mount the semiconductor die and an isolation barrier mounted to this leadframe portion in a chip-on-lead mounting. Certain remaining leads of the leadframe are isolated from the chip-on-lead portion of the leadframe. The remaining leadframe leads may have plated portions in areas designated for wire bond connections to the semiconductor die, for example silver spot plating can be used. After the bond wires are in place, a portion of the leads from the leadframes, the semiconductor die, and the dielectric die support can be covered with a protective material such as a mold compound.

In an example arrangement, a semiconductor die is cantilever mounted to an isolation barrier using die attach with a sensor or sensors on the device side surface. The sensor or sensors are placed in proximity to a conductor in the high voltage portion of the leadframe, and spaced from the high voltage portion of the leadframe by the isolation barrier. The isolation barrier is used to ensure electrical isolation between the semiconductor die and the high voltage portion of the leadframe. Bond pads on the semiconductor die are electrically coupled to leads in the low voltage portion of the leadframe. In this manner, an integrated sensor is packaged in a semiconductor device package with electrical isolation. Sensors that can be used include current sensors, magnetic sensors, position sensors and voltage sensors. Other applications for isolated semiconductor device packages include communication across differing voltage domains using coils or transformers, and coupling voltages across different power or ground domains to avoid noise coupling and ground loops. Capacitive coupling, inductive coupling and magnetic coupling can be used to transmit energy or signals across isolation barriers.

By use of the arrangements, the semiconductor die and sensor is placed in close proximity to the high voltage portion of the leadframe while the isolation barrier ensures electrical isolation between the semiconductor die and the high voltage portion. In a particular example a Hall sensor is used to sense a magnetic field corresponding to a current flowing in the conductor in the high voltage portion of the leadframe. In the arrangements, the gain of the Hall sensor is increased (over current sensor packages formed without use of the arrangements) by a reduced distance between the sensor on the semiconductor die and the high voltage portion of the leadframe. In the arrangements, the semiconductor die is mounted to the first portion of a leadframe in a flip chip mounting style, while connections from the semiconductor die to the low voltage portion of the leadframe are made with wire bonds, to form a hybrid semiconductor device package. The cost of the hybrid semiconductor device package is kept low by use of wire bond connections to the low voltage portion of the leadframe, and by use of conventional materials such as die attach epoxy, metal leadframes, and mold compound to form the semiconductor die package.

In a particular example using an existing package format, a small outline integrated circuit (SOIC) package with 16 pins is used to package a Hall-effect current sensor. Other package types can be used with the arrangements, including narrow SOIC, quad flat no lead (QFN), small outline no-lead (SON), and dual in-line packages (DIP). Use of an existing and well known package format enables low cost mounting of the semiconductor device package on a system board without need for special tooling, and without the need for modifications to existing system boards when the sensor using the hybrid package of the arrangements is used. The materials used in the arrangements and the processing steps used do not require modifications to the existing packaging processes, resulting in increased reliability at low costs.

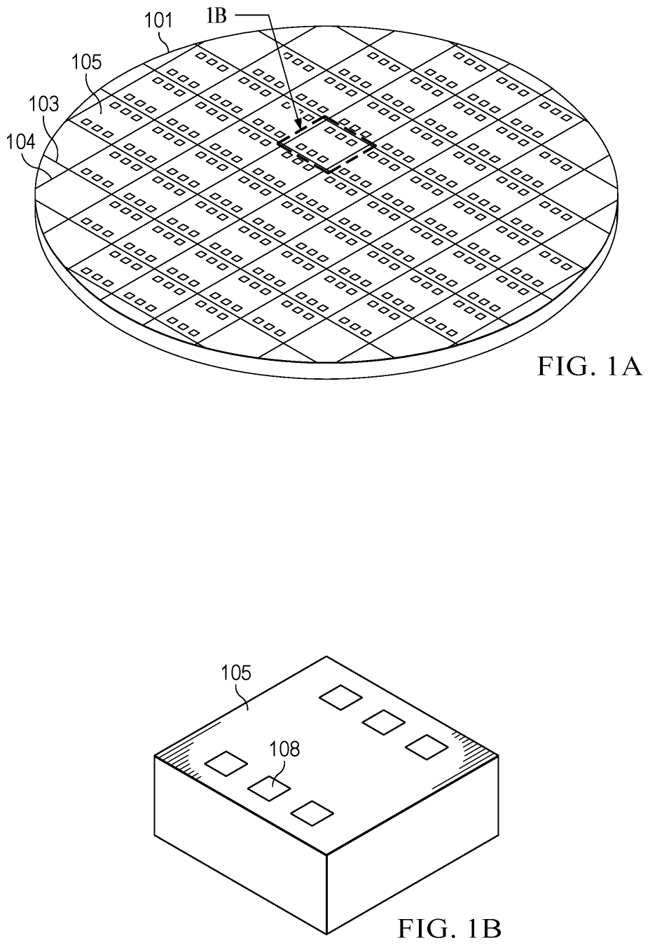

FIGS. 1A and 1B illustrate in projection views a semiconductor wafer 101 having semiconductor devices formed on it, and an individual semiconductor die 105 from the wafer for wire bonding and face up mounting, respectively. In FIG. 1A, a semiconductor wafer 101 is shown with an array of semiconductor dies 105 formed in rows and columns. The semiconductor dies 105 can be formed using processes typically used in a semiconductor manufacturing facility, including ion implantation, substrate doping, thermal anneals, oxidation, dielectric and metal deposition, sputter, photolithography, pattern, etch, strip, chemical mechanical polishing (CMP), electroplating, and other processes for making semiconductor devices on wafers. Scribe lanes 103 and 104, which are perpendicular to one another and which run in parallel groups across the wafer 101, separate the rows and columns of the completed semiconductor dies 105, and provide areas for dicing the semiconductor wafer 101 so as to separate the semiconductor dies 105 from one another.

FIG. 1B illustrates a single semiconductor die 105 from the semiconductor wafer, with bond pads 108 on a device side surface of the semiconductor die 105. The bond pads 108 are conductive pads that are electrically coupled to devices (not shown) formed in the semiconductor die 105. After the semiconductor dies 105 are completed, the semiconductor dies 105 are then separated by dicing, or are singulated, using the scribe lanes (see 103, 104 in FIG. 1A). Mechanical cutting or laser dicing, or a combination, can be used.

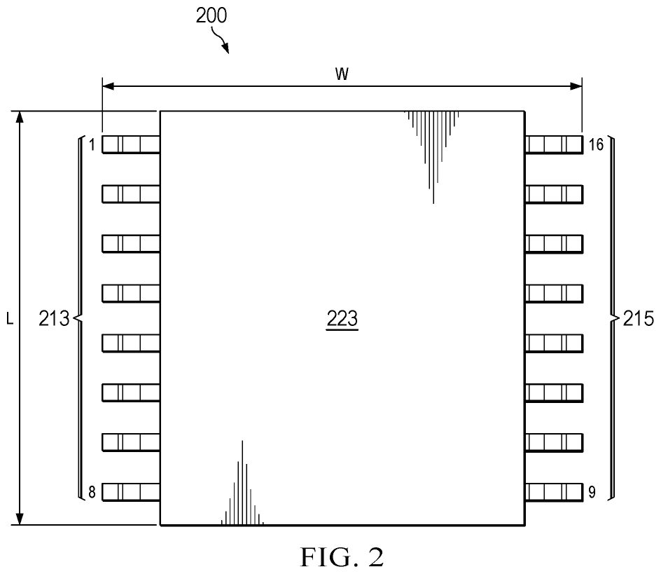

FIG. 2 illustrates, in a projection view, a semiconductor device package 200 that is useful with the arrangements. In the illustrated example, an small outline integrated circuit (SOIC) package is shown. Other leaded semiconductor packages can be used, and alternatively, no-lead packages such as quad flat no lead (QFN) packages can be used. To reduce size and volume of systems formed using semiconductor devices, reduction in semiconductor package sizes are continuously desired.

Semiconductor device package 200 includes a first set of leads 213 that are configured for coupling to a high voltage, and a second set of leads 215 that are configured for coupling to low voltages and signals including low voltage supply, control, and ground signals. The semiconductor device package 200 includes electrical isolation between the first set of leads 213 and the second set of leads 215. In an example, a wide SOIC semiconductor device package 200 has a width (labeled “W”) of about 7.5 millimeters and ranging from 3.5 to 8 millimeters, a length (labeled “L”) of about 10 millimeters and ranging from 4 to 18 millimeters, and a thickness or height of about 2.35 millimeters and ranging from 1.7 to 2.8 millimeters. Packages of various types and dimensions can be used in the arrangements. More or fewer leads 213 and 215 can be used.

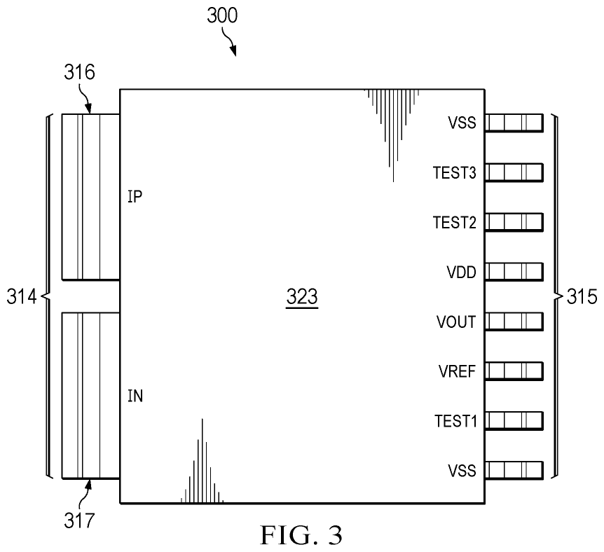

FIG. 3 illustrates a top view for an alternative semiconductor device package 300 for use with an arrangement. In FIG. 3, the first set of leads 314 are configured to be coupled to a high voltage, for example a voltage greater than 20 volts, and are configured to carry a current by being coupled in series with the high voltage. A first merged lead 316, which is a lead with a width greater than the width of a standard lead such as leads 315, is shown as an input lead labeled “IP” in FIG. 3. A second merged lead 317 is shown configured as an output lead labeled “IN” in FIG. 3. The merged leads 316, 317 are wide conductors that replace the individual leads 213 of the arrangement of FIG. 2 for the first set of leads. By replacing the standard leads with the merged leads 316, 317, the resistance of the leads is reduced and higher voltages, and therefore higher currents, can be carried by the semiconductor device package, and the current can be sensed by the semiconductor device without damage. In an example, the current can be up to seventy amperes when the wide leads are used in the high voltage portion. The wide lead are wider than the leads in the low voltage portion, at least twice as wide as the leads of the low voltage portion. The second set of leads 315 are configured for low voltage signals and supply voltages, for example a positive supply VDD, a ground VSS, and an output signal VOUT. The low voltage signals can be operational voltages used for digital semiconductor circuits, such as 6 Volts, 5.5 Volts, 5 Volts, 3.3 Volts, 2.8 Volts or less. The low voltages can include various voltages less than 20 volts. The second set of leads 315 is coupled to a semiconductor die within the semiconductor device package 300 that includes a sensor (not shown in FIG. 3). The sensor and the semiconductor die are electrically isolated from the first set of leads 314 including the first merged lead 316 and the second merged lead 317 by an isolation barrier within the semiconductor device package 300.

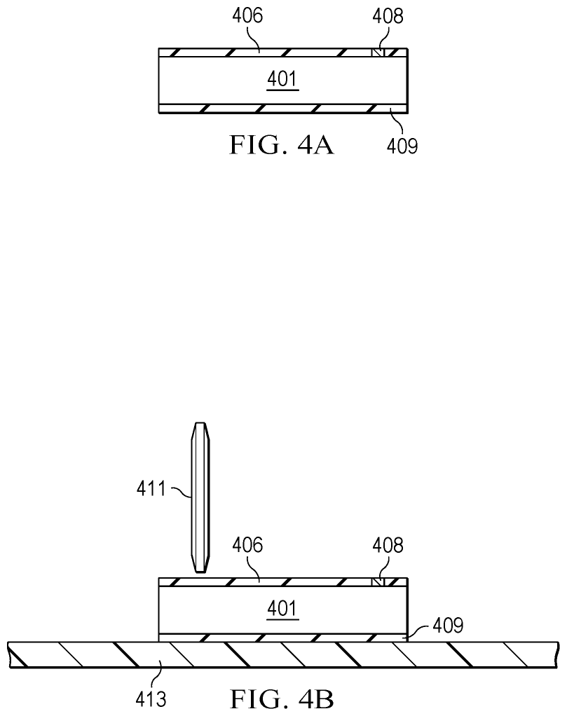

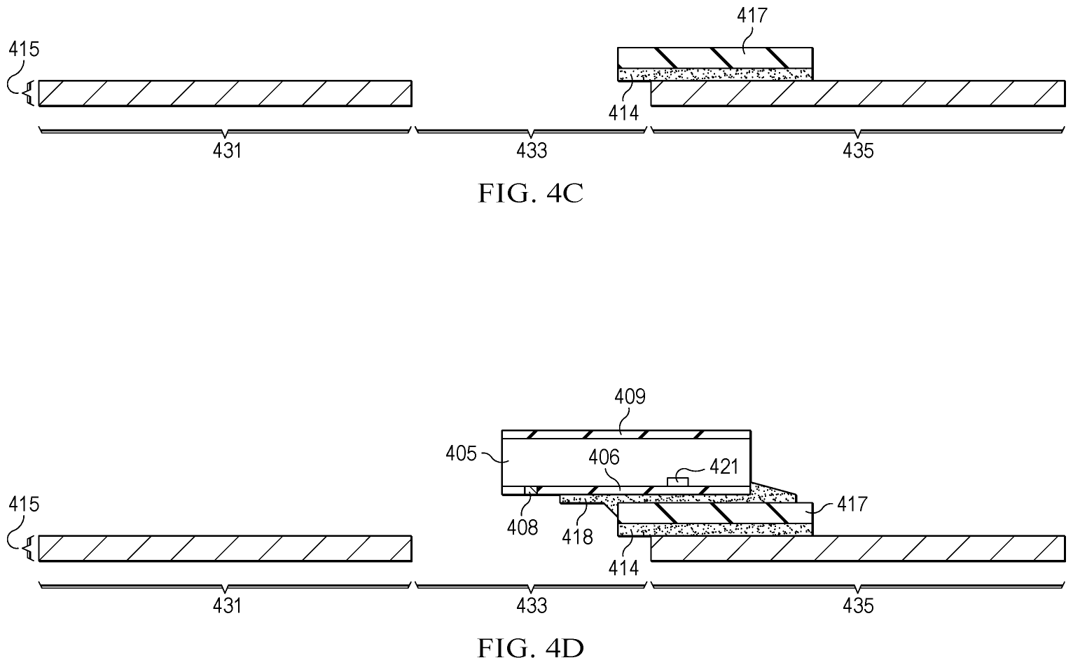

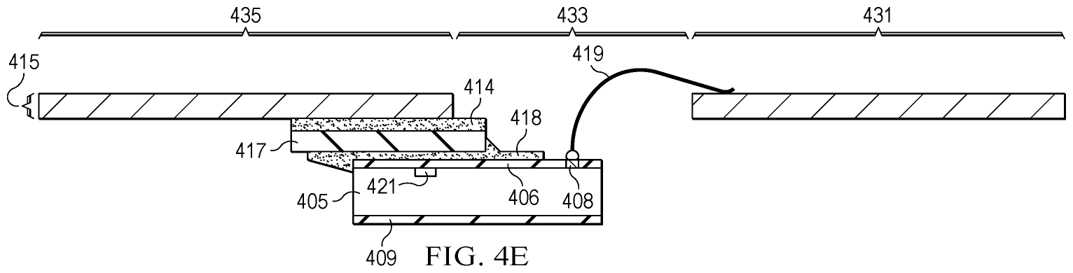

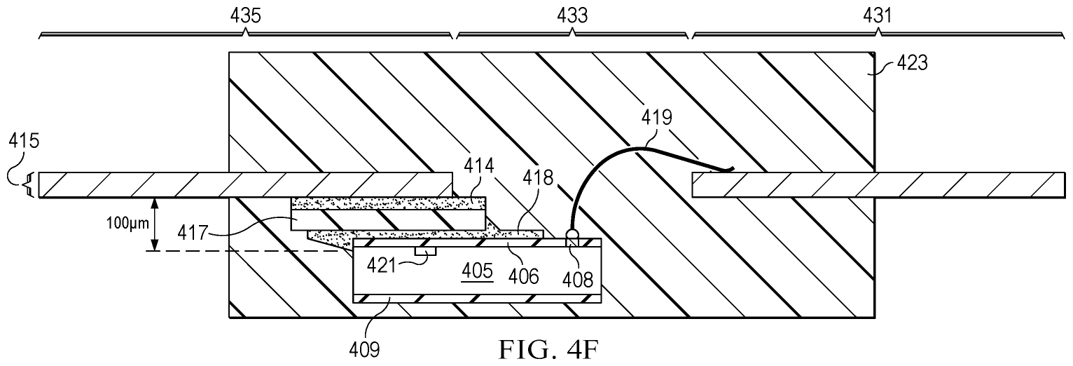

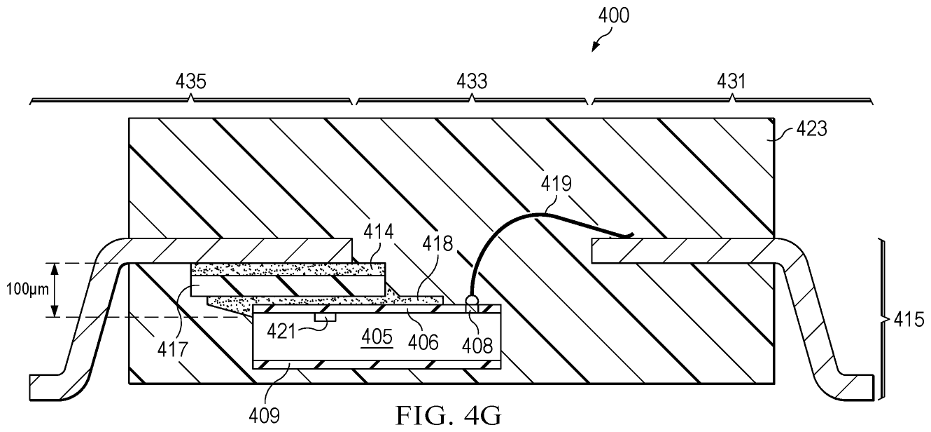

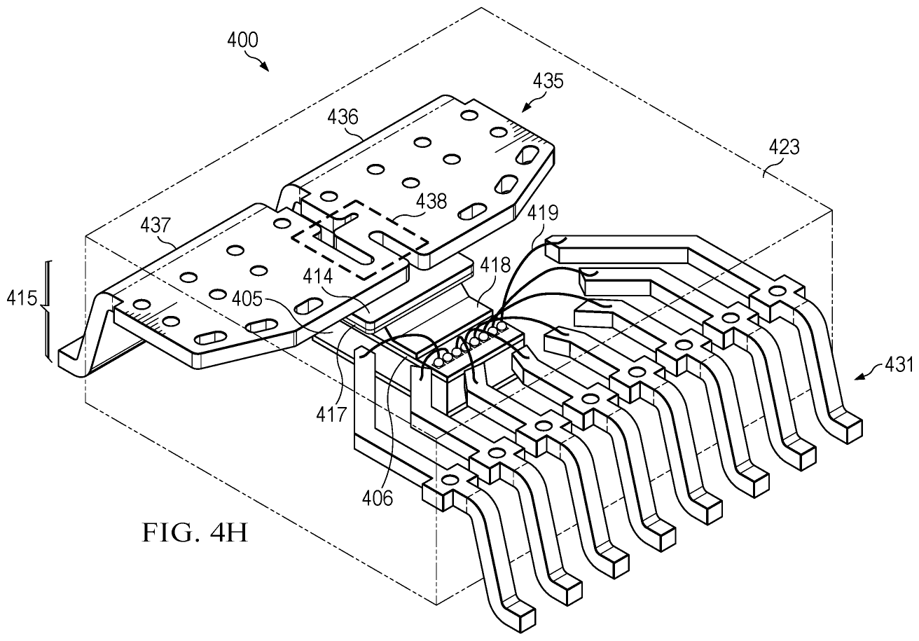

FIGS. 4A-4H illustrate, in a series of views, selected steps for forming an arrangement.

FIG. 4A illustrates, in a cross sectional view, a semiconductor wafer 401, similar to semiconductor wafer 101 in FIG. 1A, with a bond pad 408 exposed from a passivation layer 406 on a device side surface and having a backside coating 409 on a backside surface of the wafer 401 that is opposite the device side surface. The passivation layer 406 can be a polyimide material that protects the device side surface of the wafer 401. The backside coating can be a polyimide, a dielectric layer, a polymer or a dielectric film that protects the backside surface of the wafer 401. The backside coating 409 can be omitted.

FIG. 4B illustrates, in another cross sectional view, the wafer 401 in a wafer dicing operation. Referring to FIG. 1A, semiconductor dies on a semiconductor wafer have scribe lanes defined between the semiconductor dies which can be used to separate the semiconductor dies from one another in a sawing or dicing operation. FIG. 1A illustrates scribe lanes 103, 104 on wafer 101, for example. In FIG. 4B, a mechanical sawing operation is illustrated. In FIG. 4B, semiconductor wafer 401 is shown placed on a dicing support 413 which can be a removable film or tape that is provided in a frame or bracket. The wafer 401 is sawed into individual dies using a saw 411 which traverses the scribe lanes between the semiconductor dies, cutting through the semiconductor wafer 401, the passivation layer 406, and the backside coating 409, as well as any metal or dielectric layers formed on the semiconductor wafer 401 that lie in the saw streets. Bond pads 408 are shown exposed from the polyimide layer 406. In alternative dicing operations, laser dicing tools can be used, which form a stress crack along the scribe lanes, with mechanical pressure applied to dice the wafer along the cracks. Combinations of saws and lasers can be used to dice the wafer.

FIG. 4C illustrates a further processing step following the wafer dicing step shown in FIG. 4B. The steps of FIGS. 4A-4B and the step of FIG. 4C are independent from one another and can be performed at different times and at different locations. A leadframe 415 is arranged initially with the board side facing up in the example process. An isolation barrier 417 is mounted to a first portion 435 of the leadframe 415, which is configured for coupling to signals or potentials at a high voltage and includes a first set of leads. The leadframe has a central opening 433, and a second set of leads in a second portion 431 spaced from the first portion 435. The second portion 431 includes leads configured for low voltages and can be coupled to signals that operate at the low voltage. The isolation barrier 417 is mounted to the first portion 435 using a die attach epoxy or die attach film 414. Because the semiconductor device package being formed in the process includes isolation between a semiconductor die and the first portion 435 of the leadframe 415, the die attach epoxy 414 can be a non-conductive die attach material. The isolation barrier 417 can be a dielectric such as a silicon nitride, a polyimide, a polymer such as perfluoroalkyl (PFA), an epoxy, a resin epoxy, a ceramic such as aluminum nitride (AlN) or printed circuit board (PCB) materials such as fiber reinforced glass or bismaleimide triazine (BT) resin. The isolation battier 417 can have a variety of thicknesses depending on the dielectric constant and other characteristics, and useful isolation barrier thicknesses can be from 10-200 microns. However, as is explained further below, the sensor gain for an example magnetic sensor is increased (and device performance is therefore increased) when a preferred distance from the sensor on the surface of a semiconductor die to the surface of the leadframe is less than or equal to about 100 microns. The total distance includes the thicknesses of the isolation barrier, two layers of die attach material, and the passivation layer over the semiconductor die. In useful examples the isolation barrier (including a die attach layer) is about 84 microns in thickness, and the total thickness of the intervening layers between the sensor on the semiconductor die and the leadframe, including the isolation barrier and the passivation layer, is about 95 microns, which is less than the 100 micron target distance.

FIG. 4D illustrates the arrangement of FIG. 4C after additional processing. In FIG. 4D a semiconductor die 405, which is similar to semiconductor die 105 shown in FIGS. 1A-1B, is shown mounted to the leadframe 415 and to the isolation barrier 417. The semiconductor die 405 is mounted with the bond pad 408 and the device side surface of the semiconductor die 405 facing the leadframe 415, in a “flip chip” orientation. Die attach epoxy 418, which can be of the same material as die attach epoxy 414, or a similar die attach material, is used to mount the semiconductor die 405 to the leadframe 415. The semiconductor die 405 is arranged cantilevered, with a portion of the semiconductor die 405 mounted over the high voltage portion 435 of the leadframe 415, while another portion of the semiconductor die 405 including the bond pad 408 extends past the high voltage portion 435 of the leadframe 415 and is exposed in the leadframe opening 433. The semiconductor die 405 has passivation layer 406 and backside coating 409 as shown in FIG. 4A. The semiconductor die 405 in an example arrangement includes a Hall-effect device or other sensor 421. The sensor 421 is positioned with respect to the first portion 435 of the leadframe 415 to sense a parameter of the high side portion 435 of the leadframe 415. In an example the sensor 421 is a Hall-effect device that is placed in alignment with a conductor formed in the first portion 435 of the leadframe 415, the conductor carries a current that generates a magnetic field that can be sensed by the sensor 421. In additional examples, multiple sensors such as 421 can be used, and the use of multiple sensors can increase the accuracy of a current measurement.

FIG. 4E illustrates, in another cross sectional view, the elements of FIG. 4D after additional processing. In FIG. 4E the leadframe 415 and the semiconductor die 405 are shown rotated (as compared to FIG. 4C) for a wire bonding operation so that bond pads 408 are facing upwards. A bond wire 419 is shown electrically coupling the bond pad 408 on semiconductor die 405 to a lead in the low voltage portion 431 of the leadframe 415. The low voltage portion 431 of the leadframe 415 is electrically isolated from the high voltage portion 435 by spacing, by the opening 433 and by the isolation barrier 417. The wire bond connection 419 can be made using gold, copper, palladium coated copper (PCC), aluminum or silver bond wire. In an example gold bond wire of about 0.035 millimeters in diameter is used. Other diameters of bond wire can be used, depending on materials chosen for the bond wire and desired electrical characteristics of the bond wire. The cantilevered mount of the semiconductor die 405 allows the bond pads 408 to be exposed in the opening for the wire bond connection 419 to be made.

In an example wire bonding operation, a bond wire is allowed to extend through a hole in a capillary of a wire bonding tool, with an exposed end of the bond wire extending from the capillary. A heat source such as a flame or electric spark is used to melt the exposed end of the bond wire to form a ball. The molten bond wire ball is then mechanically pressed onto a bond pad of a semiconductor die using a flat face of the capillary, and in many examples, heat, pressure and ultrasonic energy is applied to create a metal to metal bond between the ball on the end of the bond wire and the bond pad. Under bump metallization (UBM) can be applied to the bond pad to increase bondability and adhesion, including nickel, gold, silver and palladium coatings and combinations of these. The bond pads can be formed of metallization material used in semiconductor processes including aluminum and copper bond pads. In an alternative approach, ribbon bonds can be used in place of the wire bonds.

After the ball is bonded to a bond pad (see for example bond pad 408 in FIG. 4E), the capillary of the wire bonding tool moves over a portion of a conductive lead and a stitch bond can be formed on the lead. The bond wire is allowed to extend from the ball bond on the bond pad through the capillary opening and arcs above the leadframe, and then is pulled down to the lead, and the capillary makes a mechanical stitch bond to the lead by pressing the wire against the lead and again using ultrasonic energy. As the capillary then moves away from the stitch bond on the lead, the bond wire is then cut a short distance from the lead. In an additional alternative wire bonding process, a “stitch on ball” bond can be used, where a first ball is bonded to the lead, the capillary of the wire bonding tool cuts the wire and then forms a second ball on the semiconductor bond pad. The wire bonding tool then extends the bond wire from the bond pad and arcs the bond wire over the first ball, and the stitch bond is made onto the first ball, to increase reliability. This stitch on ball process takes extra time (compared to ball and stitch bonding) and thus adds costs, but it can be used with the arrangements when desired. Ribbon bonds can be used in place of the bond wires.

Referring to FIG. 4E, because the semiconductor die 405 is flip chip mounted to the first portion 435 of the leadframe 415, and is wire bond (see bond wires 419) connected to the second portion 431 of the leadframe 415, the semiconductor device package can be described as a “hybrid” package, having characteristics of both a flip-chip semiconductor package and a wire bonded semiconductor package. Wire bonding allows for flexibility in the semiconductor die design and bond pad placement that is greater than for flip chip designs, in addition, in the arrangements, the use of the wire bond connections allows the leads in the second portion 431 to be spaced from the high voltages in the first portion 435 even for a small die size, adding additional isolation and flexibility.

FIG. 4F illustrates the semiconductor die 405 and the leadframe 415 of FIG. 4E after additional processing. In the transition to FIG. 4F from FIG. 4E, a molding step forms mold compound 423 that covers the semiconductor die 405 and portions of the leadframe 415, as well as covering the bond wire 419, and the isolation barrier 417. The leads of the first portion 435 of the leadframe 415 extend from one side of the mold compound 423, while the leads of the second portion 431 of the leadframe 415 extend from an opposite side of the mold compound 423, to provide terminals coupled to the semiconductor device.

As oriented in FIG. 4F, the semiconductor die 405 lies on the board side of the leadframe 415, however, in an alternative arrangement, the semiconductor die 405 may be mounted on the opposite side (top side of the leadframe 415 as shown in FIG. 4F) of the leadframe 415. In addition, in another alternative arrangement, a thermal pad or slug (not shown) could be added to the backside of the semiconductor die 405, and exposed from mold compound 423, for additional cooling if desired.

In forming example arrangements, it has been determined that for a current sensing example, the performance of the sensor is substantially improved over prior semiconductor device packages with isolation when the distance from the sensor 421 on the semiconductor die 405 to the high voltage portion 435 of the leadframe 415 is less than or equal to about 100 microns. Because in the arrangements the thickness of the semiconductor die 405 is advantageously not included in this distance, the use of the arrangements makes a lesser distance from the leadframe to the sensor possible, increasing performance of the Hall sensor by increasing sensor gain.

FIG. 4G illustrates a completed arrangement for a semiconductor device package 400, which is formed following additional processing from the illustration in FIG. 4F. The leads of the first portion 435 of the leadframe 415 and of the second portion 431 of the leadframe 415 are shaped and configured for use in a surface mount technology for attaching to a board or module. The leads are shaped using a trim and form tool and have feet or bottom portions which can be mounted to a board using a solder. The resulting semiconductor device package 400 can be an SOIC type package such as package 200 shown in FIG. 2, alternatively the semiconductor device package 400 can use the merged leads on the first portion 435 of the leadframe 415, and can appear similar to package 300 shown in FIG. 3. Other leaded package types can be used.

FIG. 4H illustrates, in a projection view, the packaged semiconductor device 400. In FIG. 4H the mold compound 423 is shown as partially transparent to illustrate additional details. The first portion 435 of the leadframe 415 is shown with a first lead 436 and a second lead 437 using the merged lead shape similar to that shown in FIG. 3. The first portion 435 of the leadframe 415 also includes a conductor 438 that is coupled between the first lead 436 and the second lead 437. In a current sensing application, the first lead 436 can be coupled as an input to a voltage source at a high voltage, and the second lead 437 can be coupled as an output so that the conductor 438 carries the current of the high voltage source. When the semiconductor device package 400 has the input lead 436 and the output lead 437 coupled in series with a load, the current flowing through the conductor 438 can be sensed by a Hall-effect sensor formed in semiconductor device 405 (see sensor 421, in FIG. 4G for example). Isolation barrier 417 is mounted to the first portion 435 of the leadframe 415 by die attach 414. The semiconductor device 405 is mounted to isolation barrier 417 by die attach 418. The passivation layer 406 is visible in FIG. 4H covering portions of the device side surface of the semiconductor die 405. The isolation barrier 417 and the die attach materials space the semiconductor die 405 from the first portion 435 of the leadframe 415, and the semiconductor die 405 is electrically isolated from the high voltages that may be carried by the first portion 435 of the leadframe 415. However, the Hall-effect sensor (see 421 in FIG. 4G) in the semiconductor die 405 can detect and sense the magnitude of a magnetic field caused by the current flowing in the conductor 438.

In FIG. 4H, bond wires 419 are shown coupling the semiconductor die 405 to the leads of the second portion 431 of the leadframe 415. These leads can be configured for carrying low voltage supplies and signals, such as power for the semiconductor die 405, control signals, output signals, clock signals, and ground signals. Use of the semiconductor device packages of the arrangements allows a semiconductor die configured for operation at low voltages to be used to sense current carried at high voltages, while the semiconductor die remains electrically isolated from the high voltages.

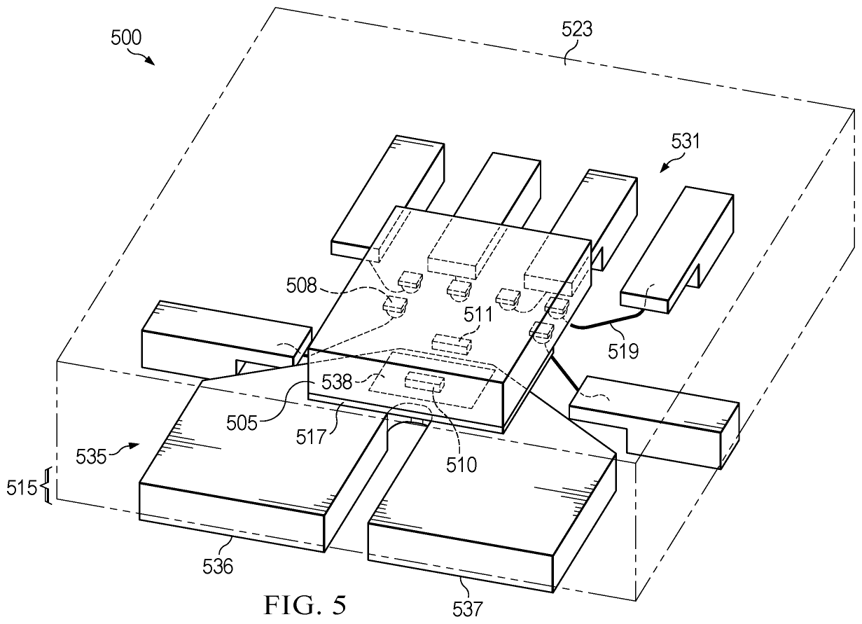

FIG. 5 illustrates, in a projection view, an alternative arrangement for a semiconductor device in a quad flat no lead (QFN) package 500. QFN packages are increasingly used for semiconductor device packages because the board area needed to surface mount a QFN package is reduced (when compared to a leaded package type such as the package 400 in FIG. 4H.)

In FIG. 5, mold compound 523 is shown as partially transparent to further illustrate the details of the arrangement. Semiconductor die 505 is shown mounted to an isolation barrier 517 that is further mounted to the first portion 535 of a package substrate 515, which can be a leadframe, a partially molded leadframe, a molded interconnect substrate or a similar package substrate arranged for providing leads for a no leads package. In the example application for current sensing, the first portion 535 of the package substrate 515 includes a first lead 536 and a second lead 537 that are configured to be serially coupled to a high voltage. A conductor 538 is formed in the first portion of the leadframe and can carry current from the first lead 536 to the second lead 537. The conductor 538 of the first portion and the semiconductor die 505 are positioned so that Hall-effect sensors 510, 511 formed on the semiconductor die 505 can detect and sense the magnetic field that is formed when current flows through the conductor 538. Use of two Hall-effect sensors can improve the accuracy of measurements and can provide the capability of reducing common noise by using a combined measurement. In an alternative arrangement, a single Hall-effect sensor can be used. The Hall-effect sensors 510, 511 are coupled to circuitry that has an output that will correspond to the magnitude of the magnetic field, in this way a magnitude for current flowing through the conductor 538 can be determined.

A second portion 531 of the package substrate 515 includes leads configured for low voltage signals and power. Bond wires 519 couple bond pads 508 on the device side surface of the semiconductor die 505 to leads in the second portion 531 of the package substrate 515. The first portion 535 of the package substrate 515, and the second portion 531, are spaced from one another and are electrically isolated from one another, the semiconductor die is mounted using an isolation barrier 517 to the first portion 535 of the package substrate 515, and so is electrically isolated from the first portion 535 and from the high voltage. Input signals such as control signals, clock signals, and enable signals and one or more output signals such as a voltage corresponding to the current level or to a magnetic field magnitude can be coupled to the semiconductor die 505 using the leads of the second portion 531. The QFN semiconductor device package 500 is a no-leads configuration, and so the leads of the second portion 531 have external surfaces that are coextensive with the surfaces of mold compound 523, which reduces the board area needed to mount the semiconductor device package 500 on a system board or module.

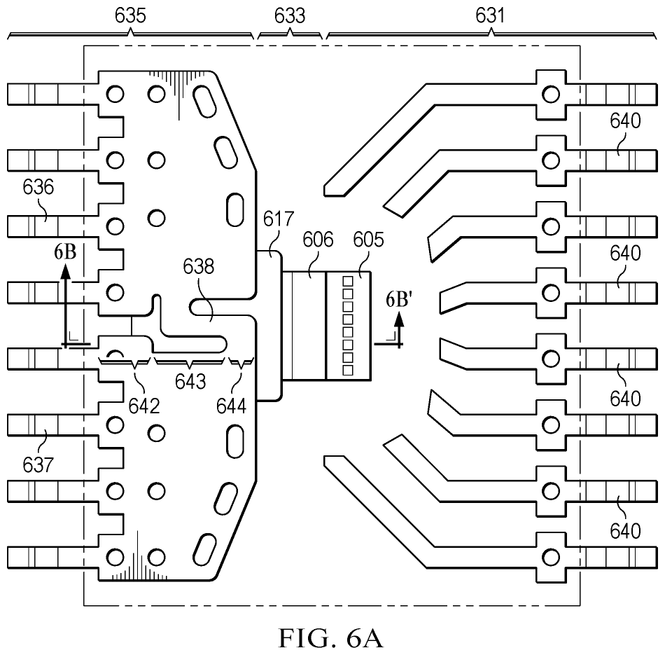

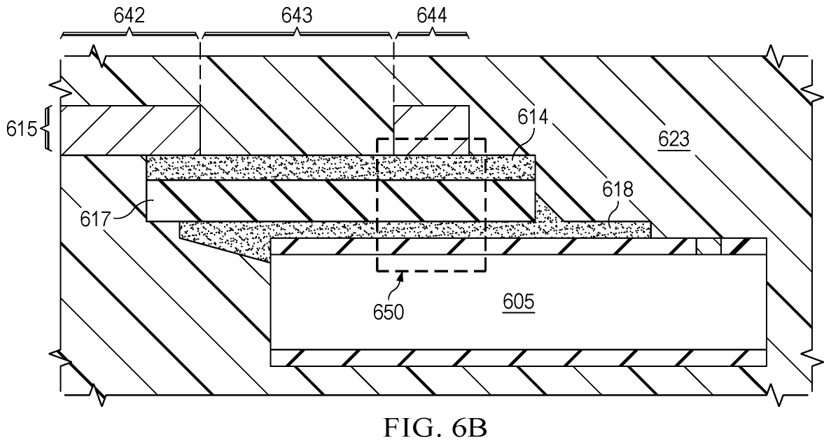

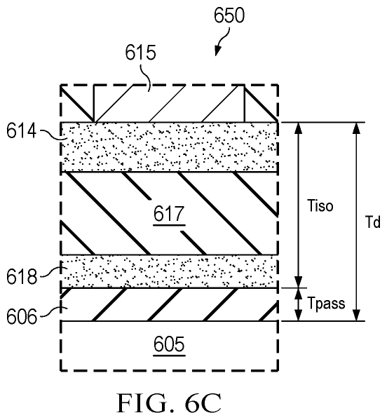

FIGS. 6A-6C illustrate, in a top view and two cross sectional views, respectively, additional details of an example arrangement. In FIG. 6A, a top view of a portion of a semiconductor device package of the arrangement is shown. For simplicity of illustration, the bond wires (see 419 in FIG. 4H, for example) are not shown. A first portion 635 of a leadframe has first leads 636 and second leads 637 which are configured to be coupled to carry current from a high voltage. A conductor portion 638 of the first portion 635 of the leadframe is positioned in correspondence with a sensor on a semiconductor die 605. The semiconductor die 605 is cantilever mounted to an isolation barrier 617 that is further mounted to the first portion 635 of the leadframe. A second portion 631 of the leadframe is spaced from the first portion 635 by an opening 633. Bond pads of the semiconductor die 605 are positioned in the opening 633 for wire bonding. The second portion 631 of the leadframe includes leads 640 which are configured for low voltage signals and supplies. A passivation layer 606 is shown covering the device side surface of the semiconductor die 605. A cross section line labeled 6B-6B′ is shown in FIG. 6A to indicate the portion that is shown in the cross section illustrated in FIG. 6B. A first area 642 is a portion of the leadframe, a second area 643 is an opening in the leadframe, filled with mold compound, and a third portion 644 is a second portion of the leadframe in FIG. 6A. The isolation barrier 617, the semiconductor die 605, die attach materials and the passivation layer 606 all lie beneath the areas 642, 643, and 644 of FIG. 6A and are shown in more detail in the cross section of FIG. 6B.

FIG. 6B is a cross sectional view taken along the line 6B-6B′ in FIG. 6A. In FIG. 6B, the semiconductor die 605 is shown cantilever mounted to the leadframe 615. The area 642 is shown over the isolation barrier 617, the area 643 that is an opening in the leadframe 615 is shown filled with mold compound 623 overlying the isolation barrier 617 and the semiconductor die 605, while the area 644 again shows a portion of the leadframe 615 over the isolation barrier 617 and the semiconductor die 605. An area 650 is shown in a further close up cross section in FIG. 6C.

FIG. 6C illustrates a close up view of a portion 650 of the cross section of FIG. 6B. In FIG. 6C, the thickness of the materials is shown. The distance labeled “Td” is a total thickness between the leadframe 615 and the semiconductor die 605 and is of particular importance. In an example using a Hall-effect device as a current sensor, the Hall-effect device responds to the magnetic field that occurs when current flows through the conductor in the first portion of the leadframe (see, for example, conductor 638 in FIG. 6A). The gain of the sensor is inversely proportional to the distance from the sensor to the leadframe. The thickness of the various layers between the device side surface of the semiconductor die and the leadframe surface determines the total distance. It has been determined that a total distance of less than 100 microns is desirable for increased performance for a Hall-effect current sensor application. However, other thicknesses can be used, less or more than 100 microns, in various arrangements.

In FIG. 6C, in an example Hall-effect current sensor, the thickness of the isolation barrier 617 and the die attach materials that is labeled “Tiso” can be about 85 microns. The passivation layer has a thickness labeled “Tpass” which, in an example arrangement, ranged between 5 and 15 microns. The total distance Td in a particular example is about 95 microns. In these example arrangements, the distance Td between the leadframe 615 and the sensor on the semiconductor die 605 is kept at about or less than 100 microns, and therefore meets the desired goal for the Hall-effect sensor to increase sensor gain. In contrast to the arrangements, for a wire bonded semiconductor device with a sensor that is formed without the arrangements, the thickness of the semiconductor die would be added to the thickness of the isolation layer, and this total thickness is substantially greater than 100 microns, and as much as 400 microns depending on the semiconductor die used, and the sensor gain is therefore substantially reduced by the thickness of the die. The use of the arrangements advantageously provides the reduced distance Td between the sensor on the semiconductor die and the leadframe, while also providing the flexibility of a wire bonded package. The arrangements use conventional semiconductor packaging materials and processes, so that the cost of using the arrangements is similar to other semiconductor device packages. Adopting the hybrid isolated semiconductor device package of the arrangements is a low cost solution to provide an isolated sensor with increased performance.

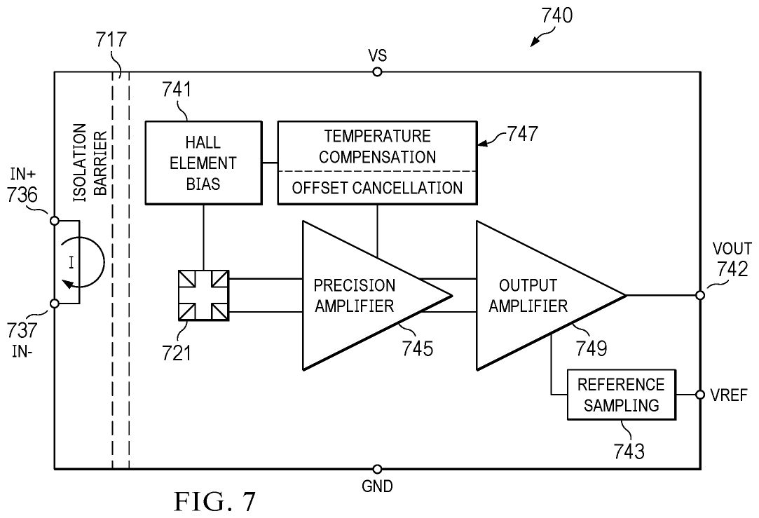

FIG. 7 illustrates in a block diagram a circuit 740 implemented on a semiconductor device that is an application for an arrangement. A Hall-effect device 721 is shown isolated from a pair of high voltage inputs 736, 737 by an isolation barrier 717. The inputs 736, 737 are configured to be coupled in series between a high voltage source and a load or output so that the load current “I” is conducted through the semiconductor device 740. The Hall-effect device 721 is coupled to a Hall element bias circuit 741, a temperature compensation circuit 747, a precision amplifier 745, which receives a differential voltage from the Hall-effect device 721, an output amplifier 749 which amplifies the outputs from the precision amplifier 745, and an output terminal VOUT 742 which outputs a voltage. In operation, the Hall-effect device 721 will respond to a magnetic field generated when current I flows through the inputs 736, 737 and the circuit 740 will output a corresponding voltage at VOUT 742. The magnetic field corresponds in magnitude to the current magnitude, and by calibration and compensation of the Hall-element, the voltage output by the Hall-effect sensor 721 is a measure of the current I. The remaining elements of the semiconductor device 740 operate at a supply voltage VS, which can be a low supply voltage for a silicon semiconductor device such as 5.5V, 3.0 V, 2.8V or less. The isolation barrier 717 and the spacing between the components provides isolation from the inputs 736, 737, which can be coupled to a high voltage that is greater than 20 volts, and up to several hundred volts. The isolation prevents damage to the semiconductor die within the package, and the isolation barrier in the packaged device allows measurements of characteristics of the high voltage system by the semiconductor device die without direct electrical connections from the semiconductor device die to the high voltage system.

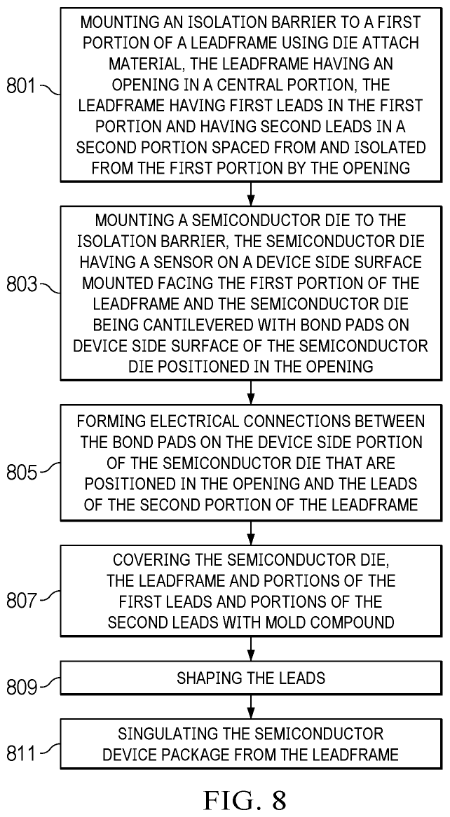

FIG. 8 illustrates, in a flow diagram, steps for forming an arrangement corresponding to the steps shown in the series of illustrations 4C-4H.

At step 801, an isolation barrier is mounted to a first portion of a leadframe using die attach material (see isolation layer 417, die attach material 419, and leadframe 415 in FIG. 4C, for example). The leadframe has an opening in a central portion, has first leads in a first portion and second leads in a second portion spaced from the first portion by the opening. (See FIG. 6A, first portion 635, opening 633, and second portion 631, for example).

At step 803, the method continues by using die attach material to mount the semiconductor die on the isolation barrier. The semiconductor die has a sensor on a device side surface positioned to face the leadframe, and the semiconductor die is mounted in a cantilever fashion with a portion of the semiconductor die including bond pads positioned in an opening in the leadframe, with the bond pads positioned in the opening in the leadframe. (See, for example, FIG. 4D, semiconductor die 405, sensor 421 positioned facing the first portion 435 of the leadframe 415, with bond pads 408 over the opening 433 in the leadframe.)

At step 805, the method continues by forming electrical connections between the bond pads on the device side of the semiconductor die that are positioned in the opening and the leads of the second portion of the leadframe. (See FIG. 4E, bond wires 419 are electrical connections between die pads 408 and the leads of the second portion 431 of the leadframe 415.) Ribbon bonds or bond wires can be used as the electrical connections.

At step 807, the method continues by covering the semiconductor die, the leadframe, and portions of the first leads and second leads of the leadframe with mold compound. (See FIG. 4F, mold compound 423 is shown covering the semiconductor die 405, and portions of the first leads of the first portion 435 and portions of the second lead of the second portion 431).

At step 809, the method continues by shaping the leads of the leadframe. This can be done in a trim and form tool, which shapes the leads in a forming step. (See FIG. 4G, where the leads of the first portion 435 and the leads of the second portion 431 are shown shaped for a surface mounting operation.)

The method ends at step 811 when the completed semiconductor device packages are separated from one another. The singulation can include a cutting or sawing operation to cut through mold compound between devices, or to cut through the leadframes between the devices. (See FIG. 4H, where the completed semiconductor device package 400 is shown).

Use of the arrangements provides a semiconductor device package with internal isolation. A package substrate, such as a leadframe, has a first portion configured for high voltage signals spaced by an opening from a second portion that is configured for low voltage signals and supply voltages. The semiconductor device package includes an isolation barrier that is mounted to the first portion, and a semiconductor die is mounted to the isolation barrier in a cantilever fashion, with part of the semiconductor die having bond pads exposed in the opening between the first portion of the leadframe and the second portion of the leadframe. The semiconductor die may include a sensor positioned to face the first portion of the leadframe. Electrical connections, which can be formed by bond wires or ribbon bonds, are made between the bond pads exposed in the opening and the leads of the second portion of the leadframe. Mold compound covers the semiconductor die, the electrical connections, and portions of the leadframe. The use of the arrangements provides a flexible, low cost, semiconductor device package with internal isolation between leads configured for high voltage signals and the semiconductor device. The sensor on the semiconductor device can sense magnetic field, temperature, voltage, and can be capacitively, inductively or magnetically coupled to the high voltage portion of the leadframe.

Modifications are possible in the described arrangements, and other alternative arrangements are possible within the scope of the claims.

What is claimed is:

1. An apparatus, comprising:
a metal leadframe comprising:
first leads in a first portion;
second leads in a second portion spaced from the first leads by an opening, the second leads isolated from the first leads;
an isolation barrier mounted to a board side surface of the first portion of the metal leadframe;
a semiconductor die having a device side surface mounted using die attach material to the isolation barrier, the semiconductor die having a sensor on the device side surface facing the first portion of the metal leadframe, the semiconductor die cantilevered and having bond pads on the device side surface exposed in the opening in the metal leadframe;
electrical connections coupling the bond pads and second leads in the second portion of the metal leadframe; and
mold compound covering the semiconductor die, the electrical connections, the isolation barrier and portions of the first leads and the second leads, the mold compound forming a package body.

2. The apparatus of claim 1, wherein the first portion of the metal leadframe further comprises a conductor that is serially coupled between one of the first leads and another one of the first leads, and the sensor on the device side surface of the semiconductor die is aligned to the conductor.

3. The apparatus of claim 2, wherein the sensor is a Hall-effect current sensor, a position sensor, an inductor, a plate of a capacitor, a transducer, or a coil.

4. The apparatus of claim 2, wherein the sensor is a Hall-effect current sensor.

5. The apparatus of claim 4, wherein the sensor is configured to output a signal indicating the strength of a magnetic field corresponding to a current flowing between the one of the first leads and the another one of the first leads.

6. The apparatus of claim 5, and further comprising circuitry on the semiconductor die coupled to and configured to receive the signal output by the sensor and to output a voltage signal on one of the second leads that is proportional to the current flowing in the conductor of the first portion of the metal leadframe.

7. The apparatus of claim 1, wherein the first leads and the second leads extend from the package body and are shaped to form terminals configured for surface mounting to a system board.

8. The apparatus of claim 1, wherein the first leads and the second leads have exposed portions that are coextensive with surfaces of the package body to form terminals of a no lead package.

9. The apparatus of claim 1, wherein the second leads have a first width, and the first leads have a second width that is greater than the first width.

10. The apparatus of claim 9, wherein the first leads have the second width that is at least twice the first width.

11. The apparatus of claim 1, wherein the first leads are configured to be coupled to a voltage that is at least twenty volts.

12. The apparatus of claim 2, wherein the conductor is configured to carry current that is greater than one ampere and up to seventy amperes.

13. The apparatus of claim 1, wherein the semiconductor die further comprises a passivation layer over the device side surface, and a distance from the device side surface through the passivation layer, the die attach layer, through the isolation barrier, and to a board side surface of the metal leadframe, is less than or equal to 100 microns.

14. The apparatus of claim 1, wherein the sensor is a Hall-effect device, and the semiconductor die further comprises:
a precision amplifier coupled to receive a differential voltage from the Hall-effect device, the differential voltage being proportional to a magnetic field corresponding to a current flowing through conductor of the first portion of the metal leadframe; and
an output amplifier coupled to the precision amplifier to boost the differential output of the precision amplifier and to output an output signal that corresponds to the current flowing through the first portion of the metal leadframe, the output signal coupled to one of the second leads of the second portion of the metal leadframe.

15. A method, comprising:
mounting an isolation barrier to a first portion of a metal leadframe, the metal leadframe having first leads in the first portion, an opening in a central portion, and second leads in a second portion spaced from the first leads of the first portion by the opening;
mounting a semiconductor die to the isolation barrier, the semiconductor die having a sensor on a device side surface that is mounted facing the first portion of the leadframe, the semiconductor die being cantilevered with bond pads on the device side surface positioned in the opening and facing the metal leadframe;
making electrical connections from the bond pads to the second leads in the second portion of the leadframe; and
covering the semiconductor die, the electrical connections and portions of the first leads of the metal leadframe and portions of the second leads of the metal leadframe with mold compound to form a packaged semiconductor device.

16. The method of claim 15, and further comprising:
cutting the first leads from the metal leadframe and cutting the second leads from the metal leadframe;
shaping the first leads and the second leads to configure the leads for surface mounting to a system board; and
singulating the packaged semiconductor device formed by the mold compound from the metal leadframe by cutting through the metal leadframe and the mold compound.

17. The method of claim 16, and further comprising:
cutting the first leads of the metal leadframe and the second leads of the metal leadframe to form terminals that are coextensive with the package body formed by the mold compound to form a no leads packaged semiconductor device; and
singulating the packaged semiconductor device formed by the mold compound from the metal leadframe by cutting through the metal leadframe and the mold compound.

18. The method of claim 16, wherein the sensor is a current sensor.

19. The method of claim 16, wherein the sensor is a Hall-effect device configured to output a voltage proportional to a current flowing in the first portion of the metal leadframe.

20. A current sensor device, comprising:
a metal leadframe comprising:
first leads in a first portion;
second leads in a second portion spaced from the first leads by an opening, the second leads isolated from the first leads;
an isolation barrier mounted to a board side surface of the first portion of the metal leadframe;
a semiconductor die having a device side surface mounted to the isolation barrier, the semiconductor die having a Hall-effect device configured as a current sensor on the device side surface facing and aligned to the first portion of the leadframe, the semiconductor die cantilevered and having bond pads on the device side surface positioned in the opening in the leadframe;
wire bond connections coupling the bond pads and second leads in the second portion of the metal leadframe, the wire bond connections extending through the opening in the metal leadframe; and
mold compound covering the semiconductor die, the electrical connections, the isolation barrier and portions of the first leads and portions of the second leads, the mold compound forming a semiconductor device package.
